(19) United States
(12) Patent Application Publication
(10) Pub. No.: US 2009/0087956 A1
(43) Pub. Date: Apr. 2, 2009

(54) Dummy Contact Fill to Improve Post Contact Chemical Mechanical Polish Topography

(75) Inventors: Satyavolu Srinivas Papa Rao, Poughkeepsie, NY (US); Mona M. Eissa, Allen, TX (US); Christopher Lyle Borst, Plano, TX (US); Noel M. Russell, Malta, NY (US); Stanley Monroe Smith, Clarence Center, NY (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/862,668

(22) Filed: Sep. 27, 2007

(51) Int. Cl. H01L 21/8238; H01L 21/4763

(52) U.S. Cl. 438/233; 438/618; 257/E21.495; 257/E21.632

(57) ABSTRACT

State of the art Integrated Circuits (ICs) encompass a variety of circuits, which have a wide variety of contact densities as measured in regions from 10 to 1000 microns in size. Fabrication processes for contacts have difficulty with high and low contact densities on the same IC, leading to a high incidence of electrical shorts and reduced operating speed of the circuits. This problem is expected to worsen as feature sizes shrink in future technology nodes. This invention is an electrically non-functional contact, known as a dummy contact, that is utilized to attain a more uniform distribution of contacts across an IC, which allows contact fabrication processes to produce ICs with fewer defects, and a method for forming said dummy contacts in ICs.

### FIELD OF THE INVENTION

This invention relates to the field of integrated circuits. More particularly, this invention relates to fabrication of contact interconnects in integrated circuits.

### BACKGROUND OF THE INVENTION

It is well known that integrated circuits (ICs) are comprised of electrical components, and may include metal oxide semiconductor (MOS) transistors, bipolar transistors, diodes, resistors, and capacitors, fabricated in and on electronic substrates, such as silicon wafers. These components are connected to one another to form electronic circuits by metal interconnects that electrically contact the components. Metal interconnects are fabricated as part of the integrated circuit manufacturing process.

Contacts are vertical metal vias connecting components of the IC with the first horizontal metal layer of interconnects, known as metal 1. Typically, each contact must be overlapped by metal 1 on top of the contact, and must connect to an active semiconductor region on the IC substrate surface or to gate material, on the bottom of the contact. Contacts are formed by etching vertical via holes through a stack of dielectric layers, known as the pre-metal dielectric (PMD), over the components in the integrated circuit, then depositing a contact liner metal and a contact fill metal, typically tungsten, over the PMD and in the vertical via holes. The contact fill metal and contact liner metal are selectively removed from the top surface of the PMD, in a manner that leaves contact fill metal in the vertical via holes even with the top surface of the PMD, typically by chemical mechanical polishing (CMP). The CMP process parameters, such as pH of the slurry, and pressure and speed of the polishing pad, are selected to remove all the contact fill metal and contact liner metal from the top surface, while minimizing removal of the PMD material.

It is well known to practitioners of contact fabrication that contact density will vary over a wide range across a given IC and from IC design to IC design. Complementary MOS (CMOS) ICs typically have higher contact densities than analog ICs. For example, static random access memory (SRAM) cell blocks may have contact densities around 17 percent, defined as the fraction of local IC area occupied by contacts, while analog components such as metal-insulator-metal capacitors and inductors may have contact densities below 1 percent. The material removal rate of the CMP process is higher in regions with a high density of contacts, because, as explained above, the CMP process parameters are selected to remove contact fill metal at a higher rate than PMD material. Conversely, the material removal rate of the CMP process is lower in regions with a low density of contacts. Thus, regions with a high density of contacts are at risk of being overpolished during the CMP process, and regions with a low density of contacts are at risk of being underpolished. Underpolished contacts can cause electrical short circuit defects. Overpolished contacts can cause excess capacitive loading of circuits. Regions with sharp transitions between high and low contact densities may exhibit non-level top surfaces of the PMD, which can lead to residual copper interconnect metal after the metal 1 level of horizontal interconnect elements is formed.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

This invention comprises a dummy contact and a method for forming same. In integrated circuits provided with dummy active, dummy gate and overlapping dummy metal 1, dummy contacts can be added to the overlap areas. In integrated circuits not provided with dummy structures, this invention includes the method of formation of dummy active, dummy gate and overlapping dummy metal 1 to support the formation of dummy contacts.

### DESCRIPTION OF THE VIEWS OF THE DRAWING

FIG. 1 is a cross-section view of an IC with an embodiment of the instant invention.

FIG. 2 is a view of an IC with existing dummy active, dummy gate and dummy metal 1, in accordance with the instant invention.

FIG. 3 is a view of an IC without existing dummy active, dummy gate and dummy metal 1, in accordance with the instant invention.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

In the discussion below, the phrase “support formation of contacts” is understood to mean modifying size, shape and location of any relevant active and gate elements so that contacts may be formed on the relevant active and gate elements in compliance with the fabrication practices appropriate to the integrated circuit containing the relevant active and gate elements, and further modifying size, shape and location of any relevant metal interconnect elements so that contacts may be formed on the relevant active and gate elements such that the relevant metal interconnect elements contact and overlap the contacts in compliance with the fabrication practices appropriate to the integrated circuit containing the relevant metal elements.

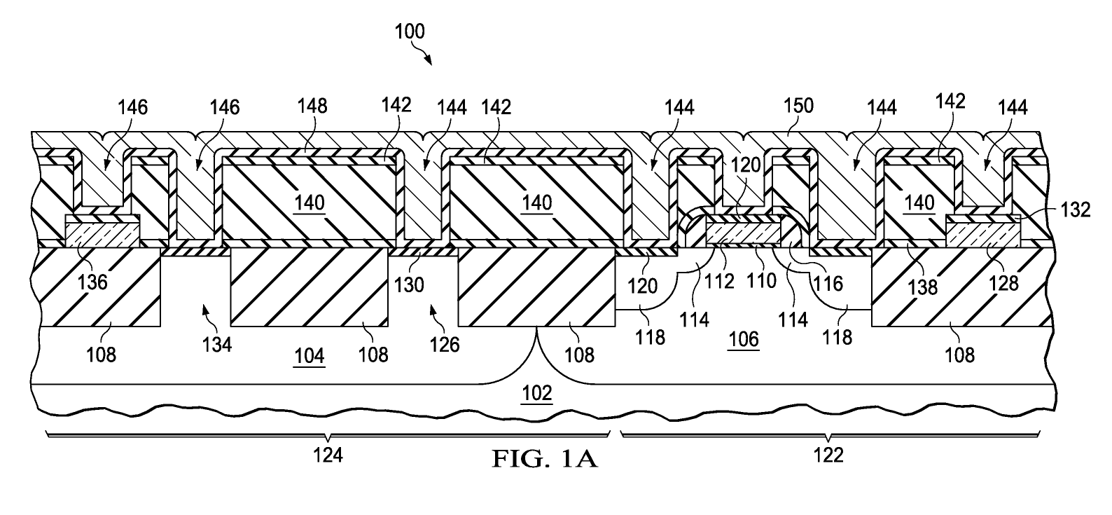

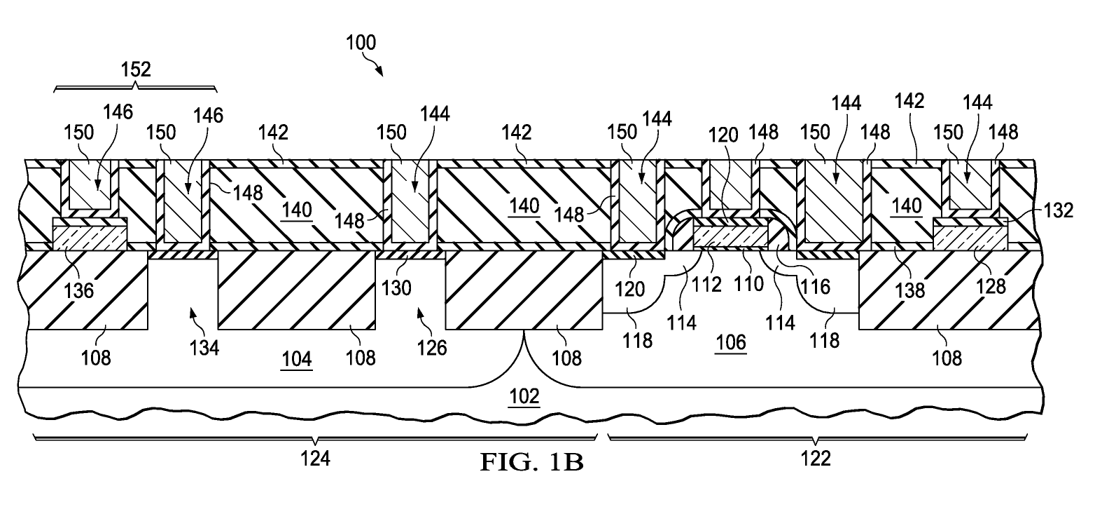

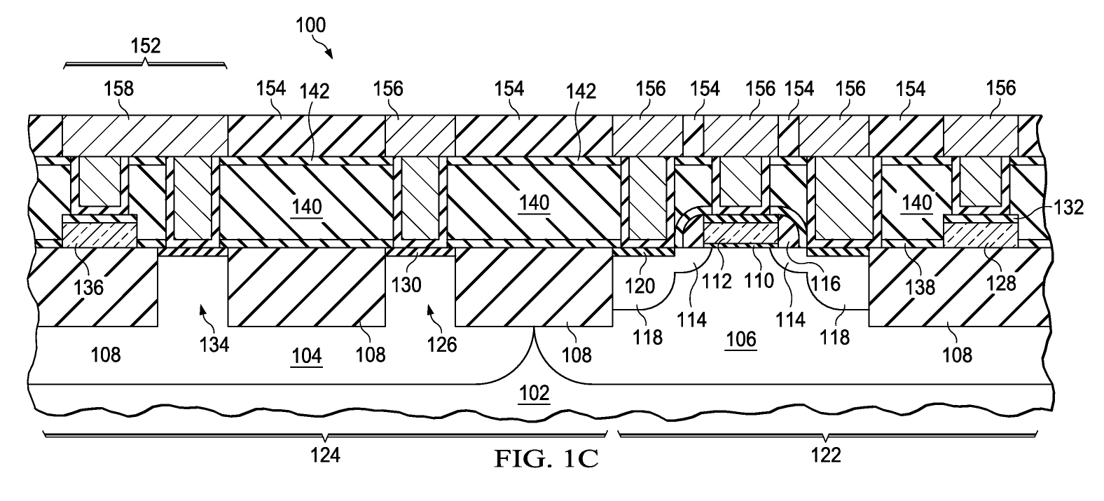

FIG. 1A is a cross-section view of an IC with an embodiment of the instant invention, depicting contacts after the contact fill metal has been deposited. An IC (100) provides a substrate (102). An n-well (104) and a p-well (106) are formed in the substrate (102), typically by ion implantation. Field oxide (108), typically comprised of silicon dioxide, is formed in the substrate, typically by shallow trench isolation (STI), to electrically isolate components in the IC (100). An n-channel MOS transistor is formed in a p-well by forming a gate dielectric (110), typically comprising silicon dioxide or hafnium oxide, forming a gate structure (112), typically comprising polycrystalline silicon, forming lightly doped source and drain regions (114), typically by ion implantation of n-type dopants, forming gate sidewall spacers (116), typically by deposition of layers of silicon nitride and silicon dioxide and anisotropic etchback, forming source and drain regions (118), typically by ion implantation of n-type dopants, and silicidation of source and drain surfaces and a top surface of the gate structure (120), typically by forming nickel silicide. P-channel MOS transistors are formed in n-wells in a similar manner, with an appropriate change in polarity of dopants.

Still referring to FIG. 1A, the IC (100) contains a high contact density region (122), wherein the area fraction of a region of the IC more than 100 microns wide and 100 microns long occupied by circuit functional contacts is equal to or greater than 10 percent, and a low contact density region (124), wherein the area fraction of a region of the IC more than 10 microns wide and 10 microns long occupied by circuit functional contacts is less than 10 percent. In each region (122, 124), functional active elements (126) and functional gate elements (128) are formed. Silicide (130, 132) is formed on the surfaces of the functional active elements (126) and the function gate elements (128). In the low contact density region (124), non-functional active elements (134), known as dummy actives, and non-functional gate elements (136), known as dummy gates, are commonly formed to improve uniformity of shallow trench isolation (STI) and gate formation processes, respectively.

Still referring to FIG. 1A, a dielectric layer stack comprising a pre-metal dielectric liner (PMD liner) (138), a pre-metal dielectric (PMD) (140) and a PMD cap layer (142) are formed over the IC to separate the first level of horizontal metal interconnects, known as metal 1, from the components in the IC. Vertical via holes (144) are formed through the PMD liner (138), PMD (140) and PMD cap (142) to reach the silicide (120) on the transistor source and drain regions (118) and the transistor gate structure (112), the silicide (130) on the functional active element (126), and the silicide (132) on the functional gate element (128). These vertical via holes (144) will be filled with metal to form functional contacts for electrically connecting the functional components of the IC.

In a first embodiment of the instant invention, non-functional contacts, known as dummy contacts, are formed on a plurality of dummy actives and dummy gates to raise contact densities in low contact density regions (124) more than 100 microns wide and 100 microns long to a value equal to or greater than 10 percent, thus providing a more uniform distribution of contact densities across the IC. Making the distribution of contact densities more uniform across the IC allows the CMP process parameters, including the polish time, to be adjusted to avoid overpolishing or underpolishing any regions of the IC. This is advantageous toward reducing costs of IC manufacture and reducing defects in ICs. The formation of dummy contacts begins by forming vertical via holes (146) over dummy active elements (134) and dummy gate elements (136).

In another embodiment of the instant invention, dummy actives and dummy gates may be placed in said regions with low contact density to support placement of dummy contacts to raise contact densities in low contact density regions to a value equal to or greater than 10 percent, thereby accruing the advantages discussed above.

Still referring to FIG. 1A, contact liner metal (148) and contact fill metal (150), typically tungsten, are deposited on a top surface of the PMD cap (142) and in contact holes (144, 146).

FIG. 1B is a cross-section view of an IC with an embodiment of the instant invention, depicting contacts after the contact CMP process has been completed. Contact fill metal (150) and contact liner metal (148) have been removed from the top surface of the PMD cap layer (142) uniformly in high contact density regions (122) and low contact density regions (124). Dummy contacts (152) have prevented low contact density regions (124) from being overpolished. Dummy contacts (152) have also prevented regions between high and low contact density regions from acquiring non-level surfaces during CMP processing. As explained above, this is advantageous toward residual copper interconnect metal after the metal 1 level of horizontal interconnect elements is formed, thus reducing defects in ICs.

FIG. 1C is a cross-section view of of an IC with an embodiment of the instant invention, depicting completed contacts and interconnect elements. A first intra-level dielectric (ILD) layer stack (154) is formed on the top surface of the PMD cap (142) and contacts. A first level of horizontal metal interconnects, known as metal 1, is formed in the ILD (154). Functional metal 1 elements (156) contact functional contacts. Non-functional metal 1 elements (158), known as dummy metal, are formed in the ILD (154) overlapping dummy contacts (152).

In cases where provided dummy metal structures do not completely overlap dummy contacts, the dummy active structures, dummy gate structures, and metal structures, in any combination, may be altered in shape and location to completely overlap dummy contacts.

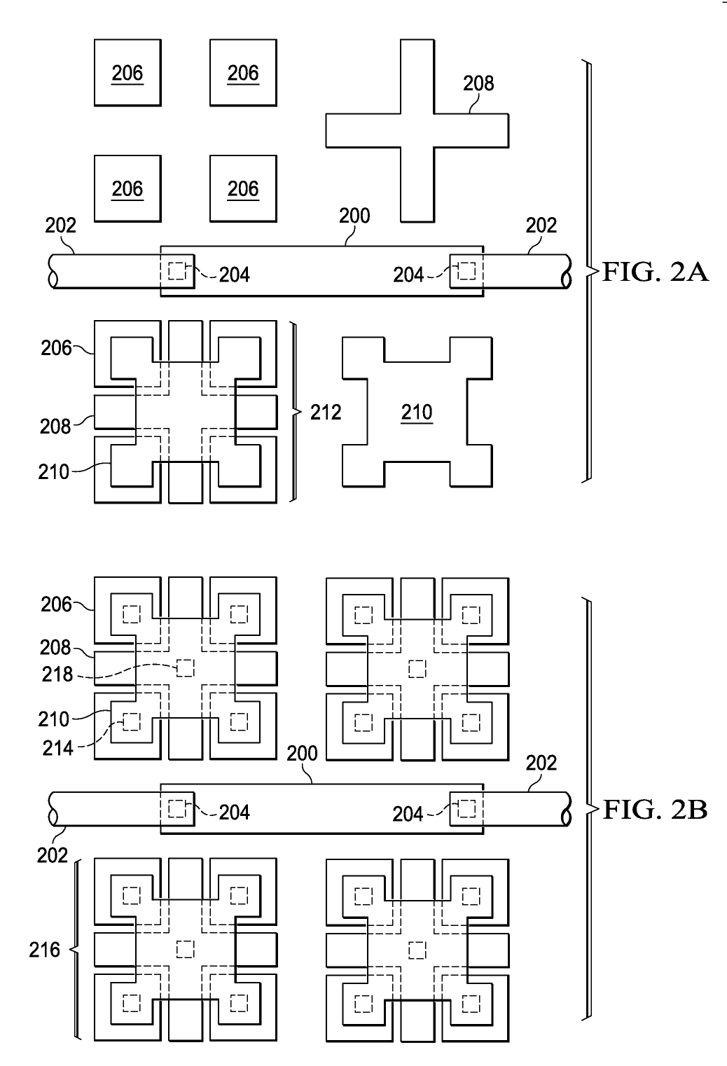

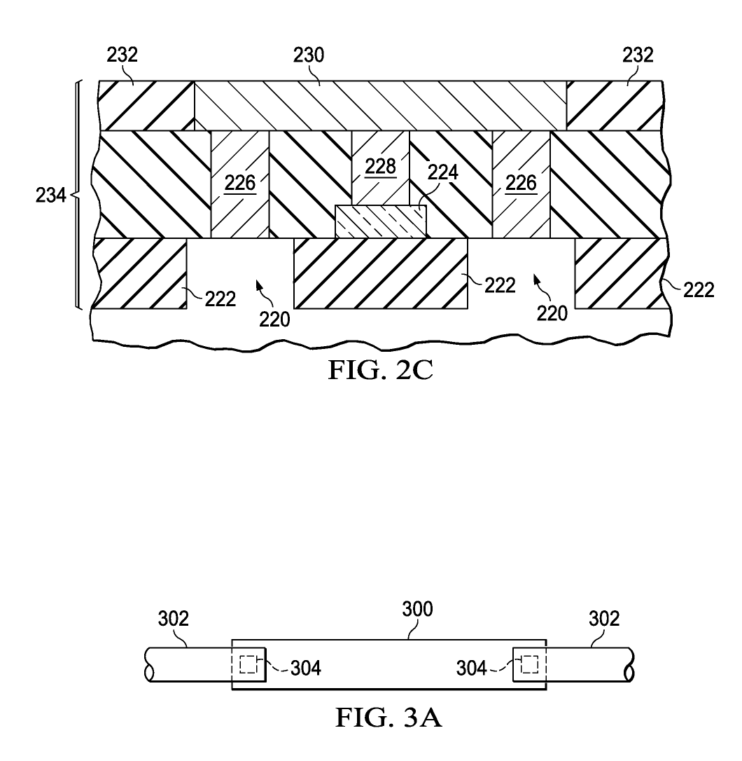

FIG. 2 is a top view of an IC with existing dummy active, dummy gate and dummy metal 1, with an embodiment of the instant invention. FIG. 2A depicts a region without this invention for purposes of comparison to FIG. 2B, which depicts a similar region with an embodiment of the instant invention. FIG. 2C depicts a cross-section of an embodiment of the instant invention.

Referring to FIG. 2A, a resistor of gate material (200) is connected to two lines of metal 1 (202) by contacts (204). No other contacts are in the vicinity of resistor (200), thus this region is a low contact density region. Dummy active (206), dummy gate (208) and dummy metal 1 (210) are provided. In this view, each dummy structure is shown separately for clarity; in typical usage, they are overlapped into a dummy structure (212).

Referring to FIG. 2B, in an embodiment of this invention, dummy contacts (214) are placed in a combined dummy structure with contacts (216) to connect dummy active (206) with dummy metal 1 (210), and other dummy contacts (218) are placed to connect dummy gate (208) with dummy metal 1 (210), whereby the density of all contacts is equal to or greater than 10 percent in regions more than 100 microns wide and 100 microns long. In cases where provided dummy metal structures do not completely overlap dummy contacts, the dummy active structures, dummy gate structures, and metal structures, in any combination, may be altered in shape and location to completely overlap dummy contacts.

Referring to FIG. 2C, dummy active (220), separated by field oxide (222), and dummy gate (224) are provided. In an embodiment of this invention, dummy contacts (226) are formed over dummy active (220), and other dummy contacts (228) are formed over dummy gate (224). Dummy metal 1 (230) is formed in ILD (232) overlapping dummy contacts (226, 228) to complete the combined dummy structure.

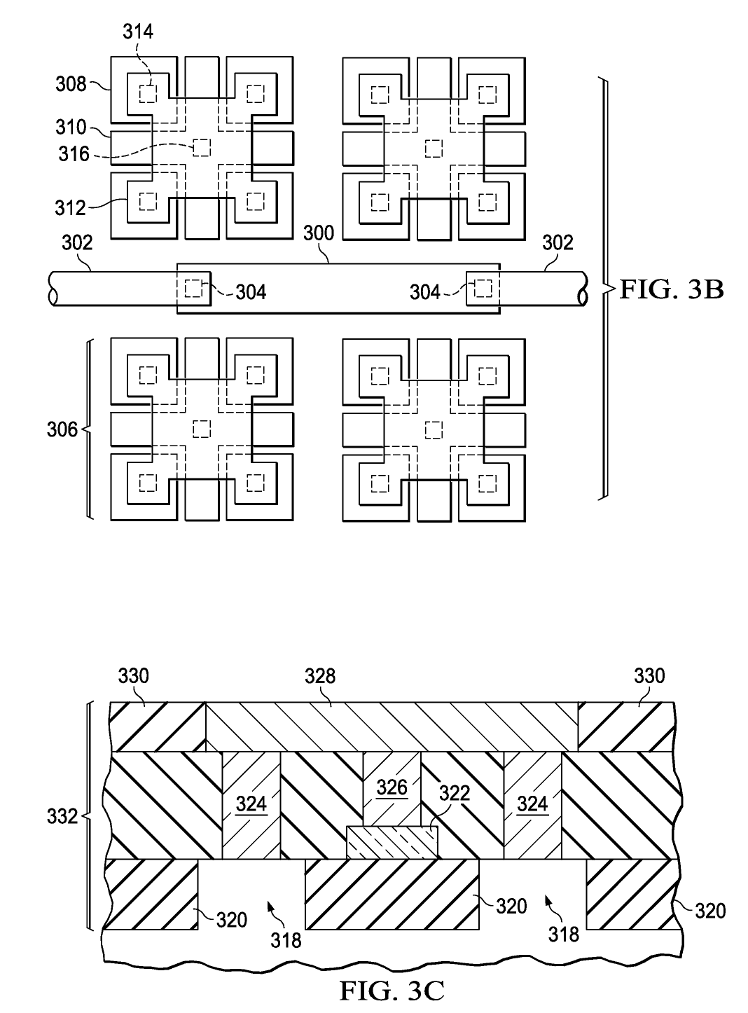

FIG. 3 depicts another embodiment of the instant invention, in a top view of an IC without existing dummy active, dummy gate and dummy metal 1. FIG. 3A depicts a region without this invention for purposes of comparison to FIG. 3B, which depicts a similar region with an embodiment of this invention. FIG. 3C depicts a cross-section of an embodiment of the instant invention.

Referring to FIG. 3A, a resistor of gate material (300) is connected to two lines of metal 1 (302) by contacts (304). No other contacts are in the vicinity of resistor (300), thus this region is a low contact density region.

Referring to FIG. 3B, in this embodiment, combined dummy structures with contacts (306) comprising dummy active (308), dummy gate (310) and dummy metal 1 (312) are placed in open areas in low contact density regions. Contacts (314) are placed in the combined dummy structures with contacts (306) to connect dummy active (308) with dummy metal 1 (312), and other contacts (316) are placed to connect dummy gate (310) with dummy metal 1 (312), whereby the density of all contacts is equal to or greater than 10 percent in regions more than 100 microns wide and 100 microns long.

Referring to FIG. 3C, in an embodiment of this invention, dummy active (318) is formed, separated by field oxide (320), dummy gate (322) is formed, and dummy contacts (324) are formed over dummy active (318), and other dummy contacts (326) are formed over dummy gate (322). Dummy metal 1 (328) is formed in ILD (330) overlapping dummy contacts (324, 326) to complete the combined dummy structure (332).

Another embodiment may be realized in regions provided with dummy active or dummy gate or dummy metal 1, but not all three elements, by placing dummy active or dummy gate or dummy metal 1 in an overlapping configuration as needed to support the placement of contacts, and placing said contacts as needed to raise the contact density to the desired range.

Another embodiment may be realized in regions provided with dummy active and dummy gate and dummy metal 1, in which the dummy structures are not arranged in an overlapping configuration sufficient to support the desired density of contacts, by altering the placements or shapes, or both the placements and the shapes, of the existing dummy structures to support the placement of contacts, and placing said contacts as needed to raise the contact density above 10 percent.

What is claimed is:

1. A method of fabricating dummy contacts in an integrated circuit, comprising the steps of:
providing a substrate;
forming dummy active structures in said substrate;
forming contacts on said dummy active structures; and
forming dummy metal interconnect structures whereby the dummy metal interconnect structures contact and overlap said contacts on said dummy active structures.

2. The method of claim 1, further comprising the steps of:
forming dummy gate structures on said substrate;
forming contacts on said dummy gate structures; and
forming dummy metal interconnect structures whereby the dummy metal interconnect structures contact and overlap said contacts on said dummy gate structures.

3. The method of claim 1, wherein the step of forming contacts on said dummy active structures further comprises the steps of:
forming a first dielectric layer on said dummy active structures;
defining regions for contacts; etching holes in said defined regions for contacts through said first dielectric layer to expose said dummy active structures in said defined regions for contacts;
depositing metal on said first dielectric layer to fill said etched holes with said deposited metal; and
removing said deposited metal from a top surface of said first dielectric layer by CMP.

4. The method of claim 2, wherein the step of forming contacts on said dummy gate structures further comprises the steps of:
forming a first dielectric layer on said dummy gate structures;
defining regions for contacts;
etching holes in said defined regions for contacts through said first dielectric layer to expose said dummy gate structures in said defined regions for contacts;
depositing metal on said first dielectric layer to fill said etched holes with said deposited metal; and
removing said deposited metal from a top surface of said first dielectric layer by CMP.

5. The method of claim 3, wherein the step of forming dummy metal interconnect structures further comprises the steps of:
forming a second dielectric layer on said contacts on said dummy active structures;
defining regions for metal interconnects;
etching in said defined regions for metal interconnects through said second dielectric layer to expose said contacts on said dummy active structures in said defined regions for metal interconnects;
depositing metal on said second dielectric layer to fill said defined regions for metal interconnects with said deposited metal; and
removing said deposited metal from a top surface of said second dielectric layer by CMP.

6. The method of claim 4, wherein the step of forming dummy metal interconnect structures further comprises the steps of:
forming a second dielectric layer on said contacts on said dummy gate structures;
defining regions for metal interconnects etching in said defined regions for metal interconnects through said second dielectric layer to expose said contacts on said dummy gate structures in said defined regions for metal interconnects;
depositing metal on said second dielectric layer to fill said defined regions for metal interconnects with said deposited metal; and
removing said deposited metal from a top surface of said second dielectric layer by CMP.

7. The method of claim 3, whereby the step of defining regions for contacts raises the contact density above 10 percent in any region of the IC more than 100 microns wide and 100 microns long.

8. The method of claim 4, whereby the step of defining regions for contacts raises the contact density above 10 percent in any region of the IC more than 100 microns wide and 100 microns long.

9. A method of forming an integrated circuit, comprising the steps of providing a substrate;
forming field oxide in said substrate;
forming an n-well in said substrate;
forming a p-well in said substrate;
forming an n-channel MOS transistor in said p-well by a process comprising the steps of:
forming a first gate dielectric on a top surface of said p-well;
forming a first gate structure on a top surface of said first gate dielectric;
forming n-type source and drain regions in said p-well adjacent to said first gate structure; and
forming a first set of silicide regions on, and in contact with, top surfaces of said n-type source and drain regions;
forming a p-channel MOS transistor in said n-well by a process comprising the steps of:
forming a second gate dielectric on a top surface of said n-well;
forming a second gate structure on a top surface of said second gate dielectric;
forming p-type source and drain regions in said n-well adjacent to said second gate structure; and
forming a second set of silicide regions on, and in contact with, top surfaces of said p-type source and drain regions;
forming dummy active structures in said substrate;
forming a pre-metal dielectric layer stack on said n-channel transistor, said p-channel transistor and said dummy active structures;
forming dummy contacts in said pre-metal dielectric layer stack on said dummy active structures; and
forming dummy metal interconnect structures whereby the dummy metal interconnect structures contact and overlap said dummy contacts.

10. The method of claim 9, further comprising the steps of:
forming dummy gate structures on said substrate;
forming dummy contacts in said pre-metal dielectric layer stack on said dummy gate structures; and
forming dummy metal interconnect structures whereby the dummy metal interconnect structures contact and overlap said contacts on said dummy gate structures.

11. The method of claim 9, wherein the step of forming dummy contacts in said pre-metal dielectric layer stack on said dummy active further comprises the steps of:
defining regions for contacts;
etching holes in said defined regions for contacts through said pre-metal dielectric layer stack to expose said dummy active structures in said defined regions for contacts;
depositing metal on said pre-metal dielectric layer stack to fill said etched holes with said deposited metal; and
removing said deposited metal from a top surface of said pre-metal dielectric layer stack by CMP.

12. The method of claim 10, further comprising the steps of:
defining regions for contacts
etching holes in said defined regions for contacts through said pre-metal dielectric layer stack to expose said dummy gate structures in said defined regions for contacts;
depositing metal on said pre-metal dielectric layer stack to fill said etched holes with said deposited metal; and
removing said deposited metal from a top surface of said pre-metal dielectric layer stack by CMP.

13. The method of claim 11, whereby the step of defining regions for contacts raises the contact density above 10 percent in any region of the IC more than 100 microns wide and 100 microns long.

14. The method of claim 12, whereby the step of defining regions for contacts raises the contact density above 10 percent in any region of the IC more than 100 microns wide and 100 microns long.

15. An integrated circuit, comprising:
provided a substrate;
a region of field oxide in said substrate;
an n-well in said substrate;
a p-well in said substrate;
an n-channel MOS transistor in said p-well comprising:
a first gate dielectric on a top surface of said p-well;
a first gate structure on a top surface of said first gate dielectric;
n-type source and drain regions in said p-well adjacent to said first gate structure; and
a first set of silicide regions on, and in contact with, top surfaces of said n-type source and drain regions;
a p-channel MOS transistor in said n-well comprising:
a second gate dielectric on a top surface of said n-well;
a second gate structure on a top surface of said second gate dielectric;
p-type source and drain regions in said n-well adjacent to said second gate structure; and
a second set of silicide regions on, and in contact with, top surfaces of said p-type source and drain regions;
dummy active structures in said substrate;
dummy gate structures on said substrate;
a pre-metal dielectric layer stack on said n-channel transistor, said p-channel transistor, said dummy active structures and said dummy gate structures;
dummy contacts in said pre-metal dielectric layer stack on said dummy active and dummy gate structures; and
dummy metal interconnect structures whereby the dummy metal interconnect structures contact and overlap said dummy contacts.

16. The integrated circuit of claim 15, wherein the contact density is above 10 percent in any region of the IC more than 100 microns wide and 100 microns long.
